(19) United States
(12) Patent Application Publication
(10) Pub. No.: US 2009/0293941 A1
(43) Pub. Date: Dec. 3, 2009

(54) Photovoltaic power farm structure and installation

(76) Inventor: Daniel Luch, Morgan Hill, CA (US)

Correspondence Address: Daniel Luch, 17161 Copper Hill Drive, Morgan Hill, CA, 95037, US

(21) Appl. No.: 12/156,505

(22) Filed: Jun. 2, 2008

(51) Int. Cl. H01L 31/048

(52) U.S. Cl. 136/251

(57) ABSTRACT

The patent teaches an installation suitable for expansive surface area photovoltaic modules. Installation structure comprises conducting rails functioning as a power conduits to convey power from expansive modules. Multiple modules may be mounted on the installation structure in a parallel or series arrangement. The high current carrying capacity rails minimize power loss in conveyance of power. Module installation and electrical connections are accomplished in a facile fashion using mechanical fasteners to thereby simplify and reduce installation cost associated with production of large photovoltaic generating facilities.

### BACKGROUND OF THE INVENTION

Photovoltaic cells have evolved according to two distinct materials and fabrication processes. A first is based on the use of single crystal or polycrystal silicon. The basic cell structure here is defined by the processes available for producing crystalline silicon wafers. The basic form of the wafers is typically a rectangle (such as 6 in.×6 in.) having a thickness of about 0.008 inch. Appropriate doping and heat treating produces individual cells having similar dimensions (6 in.×6 in.). These individual cells are normally subsequently assembled into an array of cells referred to as a module. In the module, series connections are made among the individual cells. A module may typically consist of multiple individual cells connected in series. The series connections may be made by individually connecting a conductor (tab) between the top surface of one cell to the bottom surface of an adjacent cell. In this way multiple cells are connected in a “string”. This legacy approach is generally referred to as the “string and tab” interconnection. Eventually, strings of cells are positioned and encapsulated in a box-like container. Typical dimensions for such containers may be 3.5 ft.×5 ft. Electrical leads in the form of wires or ribbons extend from cells at opposite ends of the string. These leads of opposite polarity are often directed through a junction box before connections are made to a remote load or adjacent series connected module Thus, the module can be considered its own self contained power plant.

The material and manufacturing cost of the individual crystalline silicon modules are relatively high. In addition, the practical size of the individual module is restricted by weight and batch manufacturing techniques employed. Nevertheless, the crystal silicon photovoltaic modules are quite suitable for small scale applications such as residential roof top applications and off-grid remote power installations. In these applications the crystal silicon cells have relatively high conversion efficiency and proven long term reliability and their restricted form factor has not been an overriding problem. A typical installation involves mounting the individual modules on a supporting structure and interconnecting through the individual junction boxes. Installation may often be characterized as “custom designed” for the specific site, which further increases cost. Because of cost, weight and size restrictions, use of crystalline photovoltaic cells for bulk power generation has developed only slowly in the past.

A second approach to photovoltaic cell manufacture is the so-called thin film structure. Here thin films (thickness of the order of microns) of appropriate semiconductors are deposited on a supporting substrate or superstrate. Thin films may be deposited over expansive areas. Indeed, many of the manufacturing techniques for thin film photovoltaic cells take advantage of this ability, employing relatively large glass substrates or continuous processing such as roll-to-roll manufacture of basic cell stock. However, many thin films require heat treatments which are destructive of even the most temperature resistant polymers. Thus, thin films such as CIGS, CdTe and a-silicon are often deposited on glass or a metal foil such as stainless steel. Deposition on glass surfaces restricts the ultimate module size and intrinsically involves output in batch form. In addition deposition on glass normally forces expensive and delicate material removal processing such as laser scribing to subdivide the expansive surface into individual interconnected cells remaining on the original glass substrate (often referred to as monolithic integration). Finally, it is difficult to incorporate collector electrodes over the top light incident surface of cells employing glass substrates. This often forces cell widths to be relatively small, typically about 0.5 cm. to 1.0 cm. Series interconnecting the large number of resulting individual cells may result in large voltages for a particular module which may be hazardous and require additional expense to insure against electrical shock.

Deposition of thin film semiconductors on a metal foil such as stainless steel allows expansive surfaces. However, because the substrate is conductive, monolithic integration techniques used for nonconductive substrates may be impractical. Thus, integration approaches for metal foil substrates generally envision subdivision into individual cells which can be subsequently interconnected. However handling, repositioning and integration of the multiple individual cells has proven troublesome. One technique is to use the “string and tab” approach developed for crystalline silicon cells referred to above. Such an approach reduces the ultimate value of continuous thin film production by introducing a tedious, expensive batch assembly process. In addition, such techniques do not produce modular forms conducive to large scale, expansive surface coverage requirements intrinsic in solar farms producing bulk power.

A further issue that has impeded adoption of photovoltaic technology for bulk power collection in the form of solar farms involves installation of multiple modules over expansive regions of surface. Traditionally, multiple individual modules have been mounted on racks, normally at an incline to horizontal appropriate to the latitude of the site. Conducting leads from each module are then physically coupled with leads from an adjacent module in order to interconnect multiple modules. This arrangement results in a string of modules each of which is coupled to an adjacent module. At one end of the string, the power is transferred from the end module to be conveyed to a separate site for further treatment such as voltage adjustment. This arrangement avoids having to run conductive cabling from each individual module to the separate treatment site.

The traditional solar farm installation described in the above paragraph has some drawbacks. First, the module itself comprises a string of individual cells. In the conventional module lead conductors in the form of flexible wires or ribbons are attached to an electrode on the two cells positioned at each end of the string in order to convey the power from the module. One problem is that the attachment to the cells is normally a manual operation requiring tedious operations such as soldering. Next, the unwieldy flexible leads must be directed and secured in position outside the boundaries of the module, again a tedious operation. Finally, after mounting the module on its support at the installation site, the respective leads from adjacent modules must be connected in order to couple adjacent modules, and the connection must be protected to avoid environmental deterioration or separation. These are intrinsically tedious manual operations. Finally, since the module leads and cell interconnections are not of high current carrying capacity, the adjacent cells are normally connected in series arrangement. Thus voltage builds up to high levels even at relatively short strings of modules. While not an overriding problem security and insulation must be appropriate to eliminate a shock hazard.

A unique technology for modularization of thin film cells deposited on expansive metal foil substrates is taught by Luch in U.S. Pat. Nos. 5,547,516, 5,735,966, 6,459,032, 6,239,352, 6,414,235, and U.S. patent application Ser. Nos. 10/682,093, 11/404,168, 11/824,047 and 11/980,010. The entire contents of the aforementioned Luch patents and applications are hereby incorporated by reference. The Luch modules are manufactured by optionally subdividing metal foil/semiconductor structure into individual cells which may be subsequently recombined into series connected modules in continuous fashion. The final Luch array structures can be quite expansive (i.e. 4 ft. by 8 ft., 8 ft. by 20 ft. 8 ft. by continuous length etc). Thus Luch taught modules having low cost and large form factors.

However, there remains a need for structure and methods allowing inexpensive installation of photovoltaic modules over large surface areas such as terrestrial surfaces and large commercial and possibly residential building rooftops.

### OBJECTS OF THE INVENTION

An object of the invention is to teach structure and methods allowing improved installation of photovoltaic modules over expansive surface areas.

A further object of the invention is to teach methods to reduce cost and complexity of photovoltaic power installations.

### SUMMARY OF THE INVENTION

The invention teaches structure and methodology to achieve installed photovoltaic modules covering expansive surfaces. The invention may employ large form factors of photovoltaic modules such as those taught in the aforementioned U.S. patents and U.S. Patent Applications of Luch. However, other forms of expansive modular arrays may also be employed.

In one embodiment a mounting structure suitable for receiving photovoltaic modules is constructed at the installation site prior to installation of the individual photovoltaic modules. The mounting structure may serve as a major support for the modules and may also optionally serve as a conduit for conveying the power from multiple modules.

In an embodiment a mounting structure suitable for receiving a module of extended length is constructed at the installation site. Extended length modules in roll from are shipped to the site and the module is applied to the structure by simply rolling out the module over the mounting structure. Power output connections are made at each end of the module.

In an embodiment the installed modules are supplied with environmental protection by a sheet of transparent material after the modules have been installed onto the mounting structure.

In an embodiment the modules may comprise thin film photovoltaic cells. The thin film semiconductor material may be supported on a metal foil.

In an embodiment the mounting structure comprises elongate rails which may comprise metal high current carrying capacity.

In an embodiment the module is absent flexible, unwieldy conductive wire or ribbon leads extending from the module surface.

In an embodiment the module comprises terminal bars of opposite polarity.

In an embodiment rigid electrical connection is made between a terminal bar and a rail.

In an embodiment a mounting structures comprises rails, and said rails may comprise aluminum or copper.

In an embodiment individual cells extend substantially the entire width of a module and the terminal bars are positioned at opposite ends of the module length dimension.

In an embodiment the terminal bars extend over substantially the entire width of the module.

In an embodiment the terminal bars provide an upward facing conductive surface.

In an embodiment a terminal bar has oppositely facing conductive surfaces in electrical communication.

In an embodiment the terminal bars have attachment structure such as through holes which is complimentary to attachment structure present on the metal rails.

In an embodiment a fastener is used to connect the module to a rail.

In an embodiment a fastener is a mechanical fastener.

In an embodiment a fastener is electrically conductive.

In an embodiment the fastener is a threaded bolt, and expansion bolt, a metal anchor or a rivet or U-bolt

In an embodiment a mounting structure supports a module above a base surface with a space between the module and base surface.

In an embodiment a conducting fastener serves to secure a module to a mounting structure and also convey current from said module to a conductive rail.

In an embodiment cells extend over substantially the entire width of a module and the cells are connected in series such that voltage increase progressively in the length dimension of the module while remaining constant over the module width dimension.

In an embodiment a rail is increased in cross section along its length to accommodate increasing current.

In an embodiment a rail serves as a common manifold to convey power from multiple modules.

In an embodiment a conducting rail increases in cross section with length to reduce resistive power losses.

In an embodiment a module is attached directly to a roof

In an embodiment a portion of the mounting structure may be adjusted vertically to alter the tilt of the module relative to horizontal.

In one embodiment the power conveying rails form a portion of the mounting structure for the modules.

In one embodiment the power conveying rails contribute to a frame designed for conveniently receiving a module of predetermined geometry.

In one embodiment power is conveyed from multiple individual modules at a voltage characterized as non-hazardous.

In one embodiment an existing module may be removed simply and readily replaced with a module of improved performance.

### BRIEF DESCRIPTION OF THE DRAWINGS

The various factors and details of the structures and manufacturing methods of the present invention are hereinafter more fully set forth with reference to the accompanying drawings wherein:

FIG. 1 is a top plan view of a portion of a photovoltaic module useful for the instant invention.

FIG. 2 is a sectional view taken substantially from the perspective of lines 2-2 of FIG. 1.

FIG. 3 is a simplified overall top plan view of a photovoltaic module useful for the instant invention showing some important features contributing to the invention.

FIG. 4 is a top plan view of an embodiment of a mounting structure.

FIG. 5 is sectional view taken substantially from the perspective of lines 5-5 of FIG. 4.

FIG. 6 is a perspective view showing the overall arrangement of an embodiment of mounting structure prior to installation of photovoltaic modules.

FIG. 7 is a perspective view showing multiple modules installed on the mounting structure of FIGS. 4 through 6.

FIG. 8 is a perspective view exploding the region within circle “8-8” of FIG. 7 and illustrating the details of one form of electrical and structural joining of the module to the mounting structure.

FIG. 9 is a view partially in section further illustrating the details of the mounting arrangement shown in the perspective view of FIG. 8.

FIG. 10 is a view similar to FIG. 9 showing the addition of another optional component of the expansive module.

FIG. 11 is a top plan of another structural embodiment of the novel installations of the instant invention.

FIG. 12 is a perspective view of a portion of the structure depicted in FIG. 11.

FIG. 13 is a view partially in section taken substantially from the perspective of lines 13-13 of FIG. 11 following the installation of a photovoltaic module and rigid fasteners.

FIG. 14 is a view similar to FIG. 13 of an alternate fastening structure for mounting multiple modules.

FIG. 14A is a view similar to those of FIGS. 13 and 14 showing yet another fastening structure for mounting multiple modules.

FIG. 15 is a top plan view of another embodiment of the novel supporting structure used in the installations of the instant invention.

FIG. 16 is a sectional view taken from the perspective of lines 16-16 of FIG. 15.

FIG. 17 is a view similar to FIG. 16 following an additional installation step.

FIG. 18 is a view similar to FIG. 17 following an application of additional optional materials to the FIG. 17 structure.

FIG. 19 is a side view of an arrangement to maximize radiation impingement on the arrangement of modules.

### DESCRIPTION OF PREFERRED EMBODIMENTS

Reference will now be made in detail to the preferred embodiments of the invention, examples of which are illustrated in the accompanying drawings. In the drawings, like reference numerals designate identical, equivalent or corresponding parts throughout several views and an additional letter designation may indicate a particular embodiment.

One application of the modules made practical by the referenced Luch teachings is expansive area photovoltaic energy farms or expansive area rooftop applications. In this case the installation of the expansive Luch modules can also be facilitated by the teachings of the instant invention.

The instant invention envisions facile installation of large arrays of modules having area dimensions suitable for covering expansive surface areas. In one embodiment, the teachings of the prior Luch patents are used to produce modules of large dimensions. Practical module widths may be 2 ft., 4 ft., 8 ft etc. Practical module lengths may be 2 ft., 4 ft., 10 ft., 50 ft, 100 ft., 500 ft., etc. The longer lengths can be characterized as “continuous” and be shipped and installed in a roll format. As taught in these Luch patents, such large modules can be produced in a flexible “sheetlike” form. In one embodiment, these sheetlike modules are adhered to a rigid supporting member such as a piece of plywood, polymeric sheet or a honeycomb structure. The sheetlike modules are produced having terminal bars at 2 opposite terminal ends of the module. Reference to the above mentioned Luch patents reveals these terminal bars are easily incorporated into the modules using the same continuous process as is used in assembly of the bulk module. It is noted that in his patents and applications, Luch taught that the terminal bars may have oppositely facing conductive surface regions with electrical communication between them. This is an advantage for certain embodiments of the instant invention, in that an upward facing conductive surface for the terminal bars may facilitate electrical connections.

Referring now to FIGS. 1 through 3 of this instant specification, details of a module structure appropriate for the invention are presented. In FIG. 1, a top plan view of a portion of photovoltaic module 10 is depicted. The FIG. 1 depiction includes one terminal end 12 of a module. Positioned along the edge of the terminal end 12 is electrically conductive terminal bar 14. One understands that a terminal bar of opposite polarity would be positioned at the terminal end opposite terminal end 12 (not shown in FIG. 1). In the embodiment of FIG. 1, through holes 16 have been positioned within the terminal bar 14. As will be shown, through holes 16 are used in this embodiment to achieve both structural mounting and electrical joining to the mounting structure. In addition, as is clearly taught in the Luch U.S. patent applications Ser. Nos. 11/404,168, 11/824,047 and 11/980,010, through holes such as those indicated by 16 may be used to achieve electrical communication between conductive surfaces on opposite sides of the terminal bar region. This feature expands installation design choices and may improve overall contact between the terminal bars and the conductive attachment hardware.

Continuing reference to FIG. 1 shows photovoltaic cells 1, 2, 3, etc. positioned in a repetitive arrangement. In the embodiment, the individual cells comprise thin film semiconductor material supported by a metal-based foil. This structure is more fully discussed in the referenced Luch patents. However, the invention is not limited to such structure. Alternate photovoltaic cell structures known in the art and incorporated into expansive modules would be appropriate for practice of the invention. These alternate structures include thin film cells deposited on polymeric film substrates or superstrates and those interconnected monolithically or by known “shingling” techniques. It is however helpful that the expansive module be substantially complete prior field installation and be relatively lightweight, as will be understood in light of the discussion to follow.

On the top (light incident) surface 18 of the cells in the FIG. 1 embodiment, a pattern of fingers 20 and busses 22 collect power for transport to an adjacent cell in series arrangement. The grid finger/buss collector is but one of a number of means to accomplish power collection and transport from the top cell surface. Methods such as conductive through holes from the top surface to a backside electrode, monolithically integrated structures using polymeric substrates or superstrates, and known shingling techniques may also be considered in the practice of the invention.

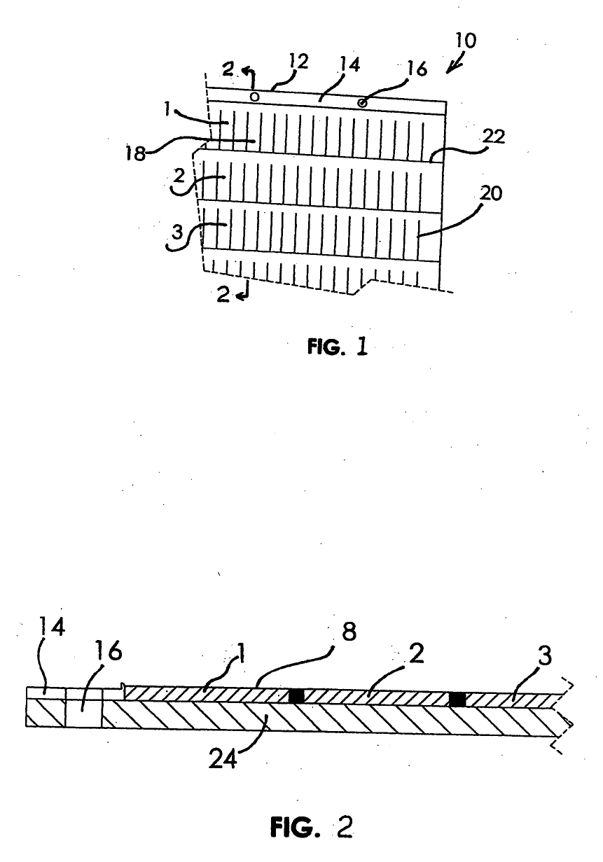

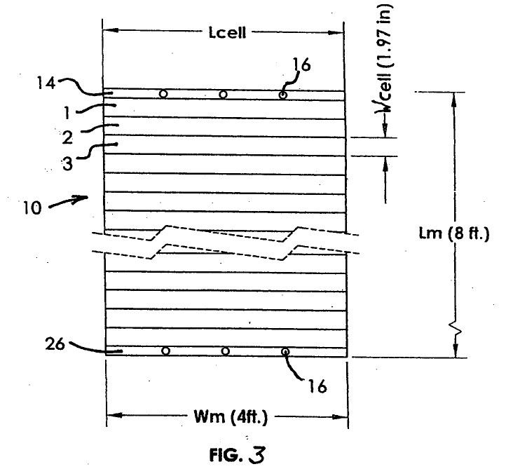

FIG. 2 is a sectional depiction from the perspective of lines 2-2 of FIG. 1. The FIG. 2 embodiment shows a series connected arrangement of multiple photovoltaic cells 1, 2, 3, etc. To promote clarity of presentation, the details of the series connections and cell structure are not shown in FIG. 2. Also shown in FIG. 2 is an optional rigid supporting structure 24. The rigid supporting structure 24 may comprise any number of material forms, such as rigid polymeric sheet, a honeycomb structure, expanded mesh, or even weatherable plywood. Supporting structure 24 may comprise a composite structure of more than one material. Structure 24 may also incorporate heat conveyance structure to assist in cooling the module. The flexible modules produced by the teachings of Luch patent application Ser. No. 11/980,010 may be adhered to the rigid support 24 using standard techniques such as structural adhesives. In FIG. 2, through hole 16 is seen to extend through terminal bar 14 and supporting structure 24. It is understood that support structure 24 may be omitted should the module 10 be attached directly to a surface such as a roof Such a direct attachment is reasonable considering the expansive modular surfaces made possible with the aforementioned Luch teachings.

FIG. 3 is a simplified top plan view of a typical module presenting an embodiment of appropriate overall structural features. In the FIG. 3 embodiment, overall module surface dimensions are indicated to be 4 ft. width (Wm) by 8 ft. length (Lm). In the following, module dimensions of 4 ft. Wm by 8 ft. Lm will be used to teach and illustrate the various features and aspects of certain embodiments of the invention. However, one will realize that the invention is not limited to these dimensions. Module surface dimensions may be larger or smaller (i.e. 2 ft. by 4 ft., 4 ft. by 16 ft., 8 ft. by 4 ft., 8 ft. by 16 ft., 8 ft. by 100 ft., etc.) depending on specific requirements. Thus the overall module may be relatively large.

At opposite terminal ends of the module, defined by the module length dimension “Lm”, are terminal bars 14 and 26. Mounting through holes 16 are positioned through the terminal bars 14, 26 and underlying support 24 as shown in FIG. 2.

In the FIG. 3 embodiment, the module is indicated to have a length (Lm) of 8 ft. The module comprises multiple cells having surface dimensions of width (Wc) (actually in the defined length direction of the overall module) and length (Lc) as shown. In the FIG. 3 embodiment, the cell length (Lc) is shown to be substantially equivalent to the module width (Wm). In addition, terminal bars 14, 26 are shown to span substantially the entire width (Wm) of the module.

Typically cell width (Wc) may be from 0.2 inch to 12 inch depending on choices among many factors. For purposes of describing embodiments of the invention, the cell width (Wc) may be considered to be 1.97 inch as shown in FIG. 3. This means that the module 10 of FIG. 3 comprises 48 individual cells interconnected in series, with terminal bars 14 and 26 of about 0.7 inch width at each terminal end of the module. Assuming an individual cell open circuit voltage of 0.5 volts (typical for example of a CIGS cell), the open circuit voltage for the module embodied in FIG. 3 would be about 24 volts. This voltage is noteworthy in that it is insufficient to pose a significant electrical shock hazard, and further that the opposite polarity terminals are separated by 8 feet. Should higher voltages be permitted or desired, one very long module or multiple modules connected in series may be considered, employing mounting and connection structures taught herein for the individual modules. Alternatively, should higher voltage cells be employed (such as multiple junction a-silicon cells which may generate open circuit voltages in excess of 2 volts), the cell width (Wc) may be increased accordingly to maintain a safe overall module voltage. At a ten percent module efficiency, the module of FIG. 3 would generate about 290 Watts.

One realizes the module structures depicted in FIG. 1 through 3 may be readily fabricated at a factory and shipped in bulk packaging form to an installation site.

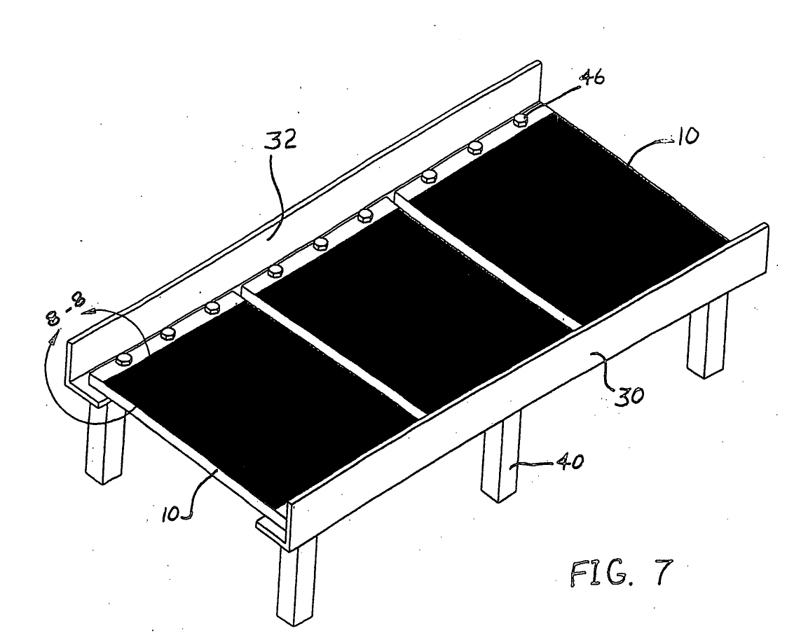

FIG. 4 is a top plan view of a portion of one form of field mounting structure, generally indicated by numeral 28. FIG. 6 is a perspective view of the portion 28. In the structural and process embodiments herein described, the mounting structure may be pre-constructed at the site prior to combination with modules 10 as depicted in FIG. 3. For example, should a terrestrial installation be desired, appropriate land grading and support construction could be completed in advance of the arrival of the modules.

FIGS. 4 and 6 show that the mounting structure 28 comprises 2 parallel elongate rails 30 and 32. In this embodiment, rails 30 and 32 are oriented, spaced and have structure appropriate to readily receive modules. For example, in the embodiment of FIG. 4 the rails have an open or “receiving” dimension (shown as 96.125 inch in the embodiment) slightly larger than a length dimension (Lm) of a module. The outline of a module such as that of FIG. 3 is depicted in phantom by the dashed lines in FIG. 4. The rails 30, 32 will normally extend a distance (Lmr) greater than the combined aggregate width (Wm) of multiples of the expansive surface area photovoltaic modules.

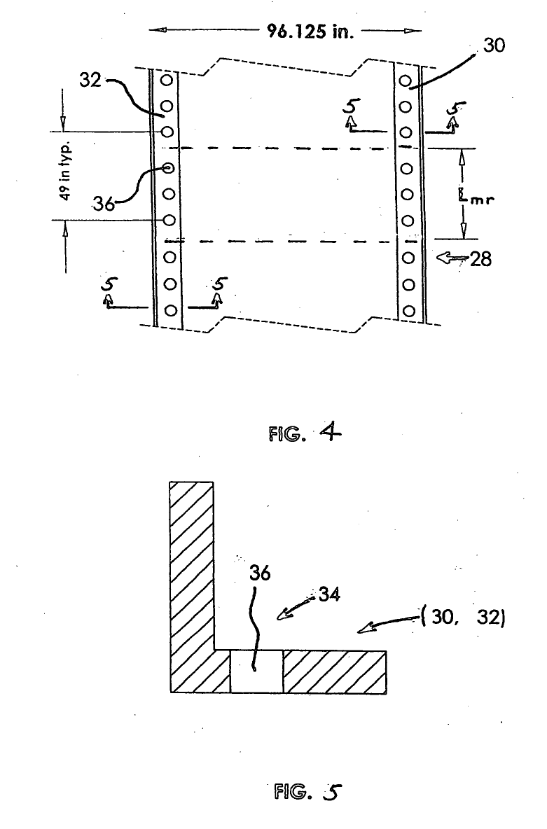

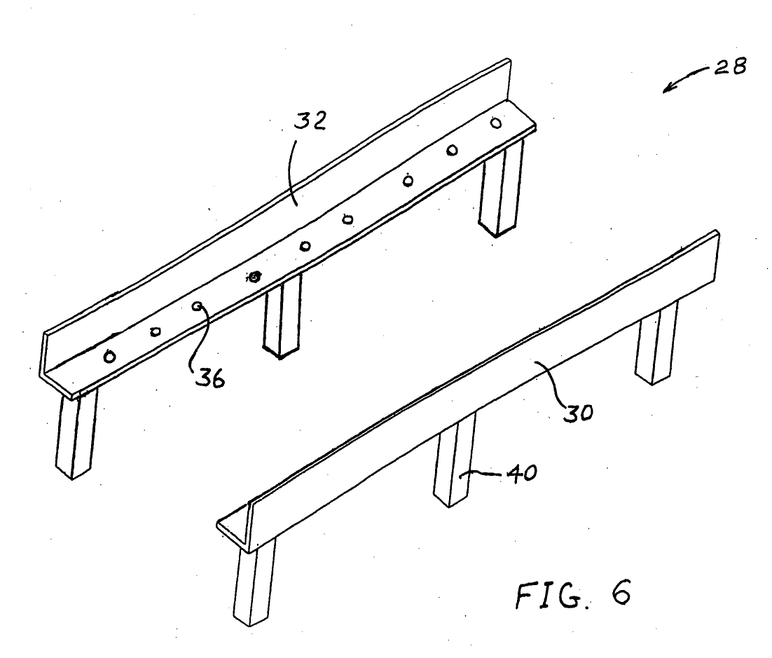

FIG. 5 is a sectional view taken substantially from the perspective of lines 5-5 of FIG. 4 and shows the details of one form of structure for rails 30, 32. In the FIG. 5 embodiment the rails comprises a 90 degree angle structure of an elongate form of metal such as aluminum. The angle forms a seat 34 to receive the photovoltaic module. Holes 36 through the metal rails are sized and spaced to mate with the holes 16 in modules 10. Holes 36 may have a smooth bore or be structured such as with a thread pattern to receive a threaded mounting bolt.

The rails 30, 32 comprise a material such as aluminum or copper or metal alloys which are relatively inexpensive, strong and have high conductivity. The rails can comprise more than one metal or alloy. Surface coatings or treatments or additional materials known in the art may be employed to prevent environmental corrosion and deterioration of contacts. As will be shown in the embodiments of FIGS. 7 through 10, the mounting rails 30, 32 may function also as power conduits or primary busses from a multiple of individual photovoltaic modules 10.

The rails may be supported above a base or ground level by piers or posts 40 emanating from the ground. Alternatively, they may be attached to additional structure such as a roof The rails 30, 32 may be at different elevations so as to tilt the arrays at a given angle according to the latitude of the installation site.

FIG. 7 shows the result of attaching multiple modules (3 in the FIG. 7 embodiment) to the elongate rail structure. The rails have a structure which mates dimensionally with the sheetlike structure of the modules such that the sheetlike module 10 is easily positioned appropriately with respect to the rail structure. Electrical connection between the terminal bars 14, 26 disposed at the two opposite ends of the module 10 and the rails 30, 32 is simultaneously achieved through the mechanical joining of the module sheets to the rails. The terminal bars of a first polarity of the multiple modules are attached to a first rail and the terminal bars of the opposite polarity are attached to the second opposing rail. It is noted that in this embodiment the multiple modules are connected to rails such that each rail serves as a common manifold for conveyance of power associated with multiple modules and there is no need for coupling of components from the adjacent modules. Thus, current accumulates in the rails as they span multiple modules but the voltage is envisioned to remain substantially constant.

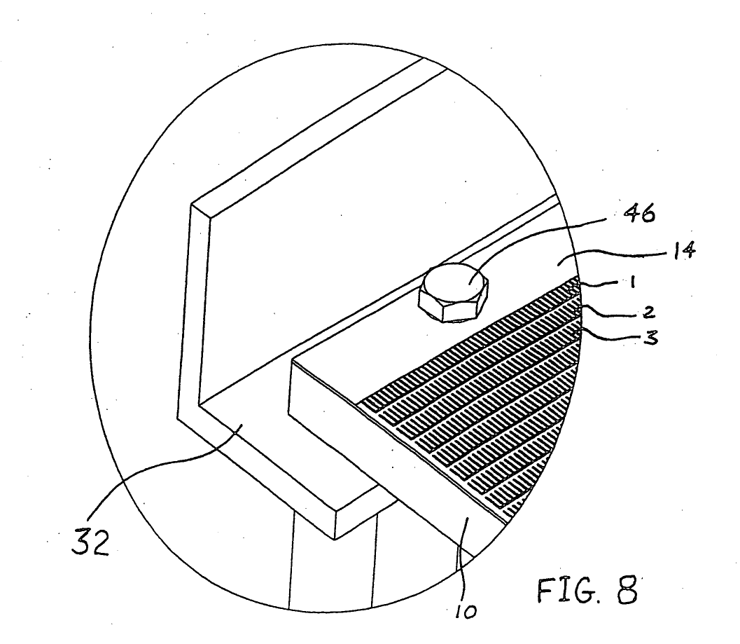

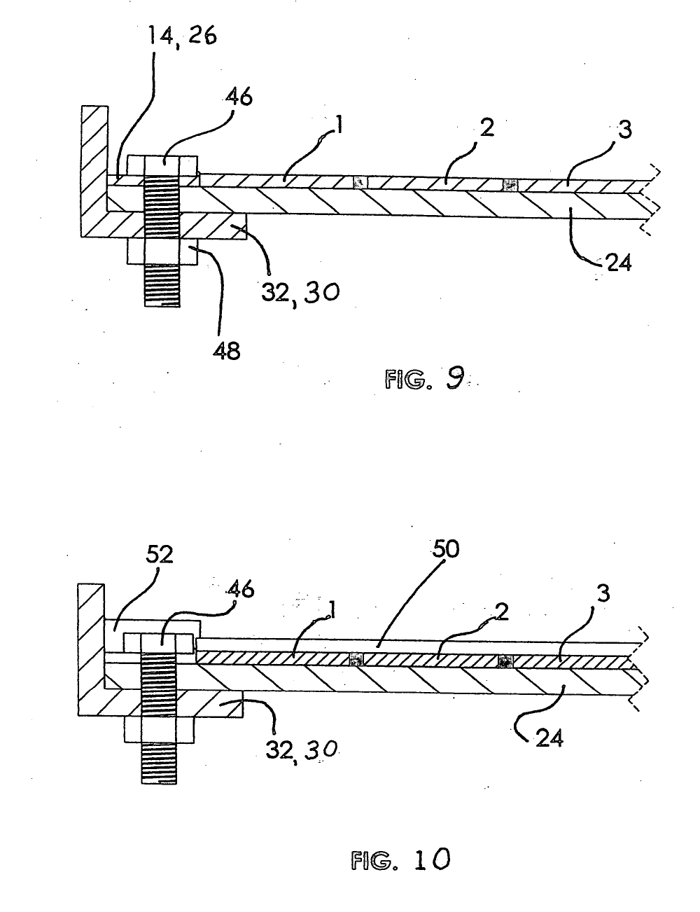

FIGS. 8 and 9 embody details of one form of mechanical joining which simultaneously accomplishes electrical communication between terminal bars 14, 26 and rails 32, 30. The FIGS. 8 and 9 show that the modules are quickly and easily secured to the angled rails using mechanical fasteners such as the metal bolts 46 shown extending through the oppositely disposed module terminal bars, the module support and the metal angle rails. Other conductive mechanical fasteners may be employed such as rivets and expansion bolts (toggle bolts for example) and metal anchors. Also, other hardware and materials (not shown) such as washers and conductive compounds known in the art may be considered to improve surface contact between the bolts 46, terminal bars 14, 26 and rails 32,30. One appreciates that materials used for the fasteners should be non-corrosive such as stainless steel in order to assure longevity of contact. It is noteworthy that no wires or metal ribbons are required to achieve this simultaneous mechanical and electrical joining. Thus there is no need for electrical leads such as unwieldy wires or ribbons emanating from the module. Further there is no need for processes such as soldering to achieve the mechanical and electrical mounting. The bolts shown in the FIGS. 7 through 10 embodiments are very robust, quick and simple to install and provide a low resistance connection resistant to breakage and environmental deterioration. In FIG. 7, multiple bolts 46 at each module end (3 shown) minimize contact resistance between the module terminal bars 14, 26 and the angle material and provide redundancy of contact. In this way the power generated in the expansive module is transferred to the supporting rails 32, 30. Thus module mounting and electrical connection to the rail “power conduit” is achieved easily and quickly without any separate wiring requirement. In addition, the mechanical mounting and electrical connection envisioned allows facile removal and replacement of a module should it become defective or future technology produces largely improved performance justifying such replacement.

FIG. 10 embodies a structure similar to FIG. 9 but including an optional additional component 50. Component 50 comprises a sheetlike transparent cover for the module and may comprise glass or a transparent polymer such as polycarbonate, acrylic, or PET. The purpose on the transparent sheet is to afford additional environmental protection to the thin film photovoltaic cells. For example, certain thin film semiconductors such as CIGS are susceptible to environmental deterioration and can be protected by such a transparent environmental cover. It is envisioned that protective cover sheet 50 may be installed after installation of the photovoltaic module by simply laying it over the top of the module. Alternatively, the cover 50 may be applied at the factory prior to shipment and site installation. It is further envisioned that a sealing member, such as depicted by numeral 52 in FIG. 10, may be employed to fix the transparent sheet in position and provide edge sealing. It may be advantageous for such a sealing member 52 to be semi-permanent, such as would be the case for a conformable weather stripping material. In this way the module may be easily removed and repaired or replaced as necessary. One also will appreciate that a sealing member 52 may be appropriate even in the absence of sheet 50 in order to protect contact surfaces from environmental deterioration and provide edge protection to the module.

As shown in FIG. 7, multiple sheetlike modules 10 are attached to the rails repetitively in a linear direction along the rails. Each of the modules produces substantially the same voltage, but the current increases each time the rails span an additional module. In this way the installation is a simple placement of the expansive surface modules relative the supporting rails and the mechanical fastening of the modules to the rails (using conductive, mechanical joining means such as nuts and bolts) allows current to flow from the individual module to the supporting rails, with the rails also serving as a conductive buss or power conduit of high current carrying capacity. The elongate rails lead to a collection point where the accumulated power is collected and optionally transferred to a larger master buss for additional transport or the power is converted from “high current/low voltage” to “high voltage/low current” power to achieve more efficient transport.

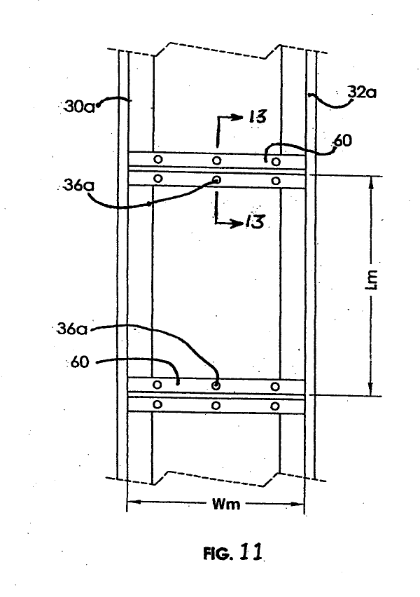

Referring now to FIG. 11, another embodiment of an installation structure according the invention is shown in top plan view. This structural embodiment also comprises rails 30a, 32a. In the FIG. 11 embodiment, rails 30a, 32a need not be electrically conductive as will be understood in light of the teachings to follow. Additional cross rails 60 span the separation between rails 30a, 32a. These cross rails 60 have an elongate structure as shown and in an embodiment may be electrically conductive. The repetitive distance between the elongate cross rails is slightly greater than the length (Lm) of a module (for example 96.125 inch for a module of eight foot length). Cross rails 60 also comprise holes 36a which, as will be seen, are positioned to mate with complimentary holes extending through the terminal bars of modules to be eventually positioned on the FIG. 11 structure. Finally, the rails are characterized as having a width dimension (Wm) slightly larger than the width of the eventual module. Thus the rails 30a, 32a, 60 form a convenient receptacle or frame within which a module may eventually be positioned.

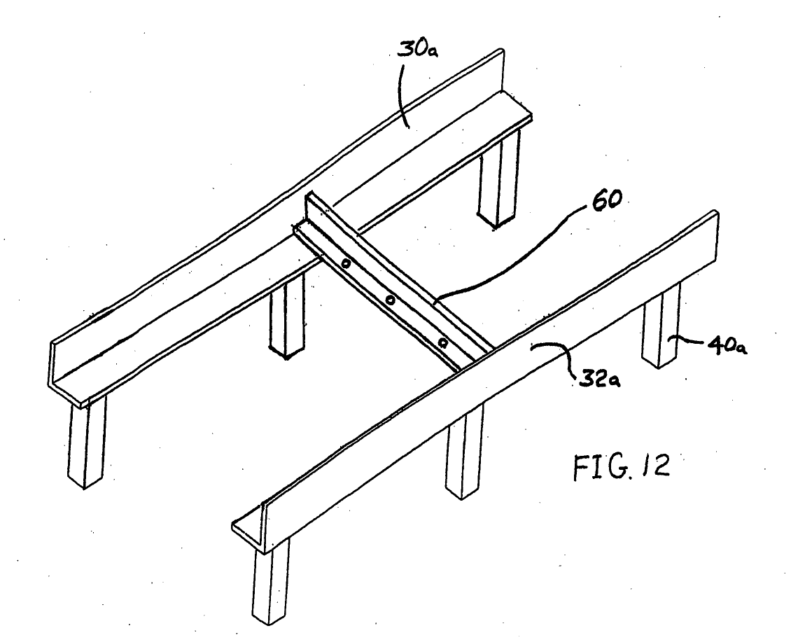

FIG. 12 is a perspective view of a portion of the FIG. 11 structure. In FIG. 12 it is seen that the rail structure 30a, 32a, 60 may be supported on piers 40a above a base level as previously illustrated for the FIG. 6 embodiment.

FIG. 13 is a view in partial section taken substantially from the perspective of lines 13-13 of FIG. 11, but following installation of modules. In this FIG. 13 embodiment, elongate cross rail 60 comprises electrically conductive material, normally a metal. Two modules are generally indicated in FIG. 13 by the numerals 10a, 10b and the individual series connected cells by the numerals 1a, 1b, etc. FIG. 13 shows that cross rail 60 has the shape of an inverted “tee” having holes 36a on arms 49 and 62 of the “tee”. The terminal bar 14a of module 10b is fastened to a first arm 49 of the “tee” form of cross rail 60 using conducting metal threaded bolts 46a and nuts 48a. The head 47a of bolt 46a contacts a top conductive surface of terminal bar 14a. Additional washers and conductive compounds may be used as appropriate to improve surface contact between fastener features and conductive surfaces. Application of the nut 48a securely fastens module 10b to the arm 49 and supplies electrical communication between terminal bar 14a and arm 49. A similar fastening arrangement secures and electrically connects the terminal bar 26a of module 10a to the second arm 62 of cross rail 60. Since in this embodiment the cross rail 60 is conductive, electrical communication is established between terminal bar 14a of module 10b and opposite polarity terminal bar 26a of module 10a. The two modules are thereby simply, inexpensively and robustly connected in series.

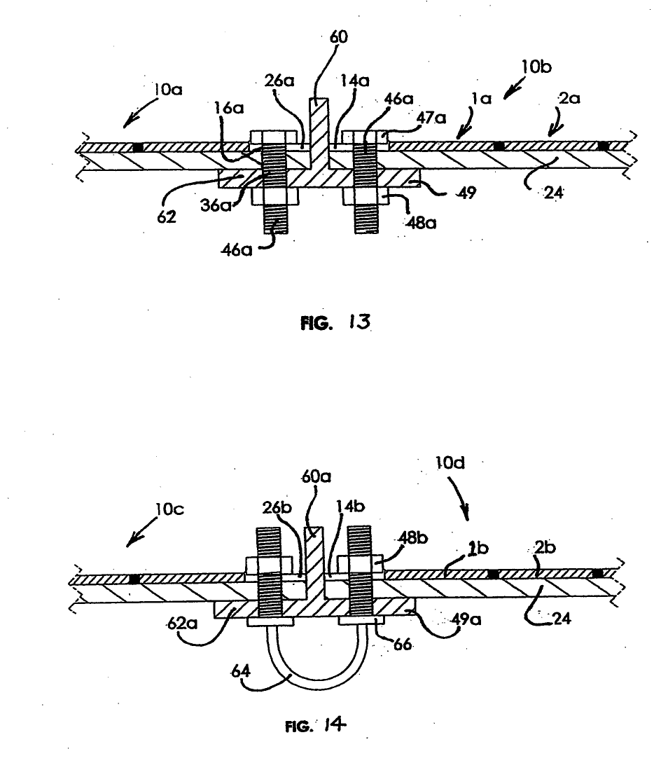

FIG. 14 shows an arrangement partially in section similar to FIG. 13 but illustrating a different form of fastening and connection. In the FIG. 14 embodiment, cross rail 60a is seen to be of cross section similar to that of cross rail 60 in FIG. 13. However, in the FIG. 14 embodiment, elongate cross rail 60a need not necessarily comprise conductive material. In FIG. 14, first terminal bar 14b of module 10d is secured to a first arm 49a of cross rail 60a using one end of a “U-bolt” type connector. In the embodiment, secure attachment of module 10d to rail 60a is achieved by threading of nut 48b such that it pulls flange 66 tightly against the bottom of arm 49a as shown. A similar attachment is made to terminal bar 26b of module 10c. Contact of the respective nuts 48b with the upper conductive surfaces of terminal bars 14b and 26b of modules 10d and 10c respectively connect the two modules in series through the rigid conductive “U-bolt” fastener. Module mounting is rapid, inexpensive and simple.

FIG. 14A shows another embodiment of a series connection among adjacent modules. In FIG. 14A the “tee” shaped rails 60 or 60a of FIGS. 13 and 14 respectively are replaced by a simple flat rail in the form of a strap 60b. Modules 10e and 10f may have a slight separation between them as shown at 55 but are in close enough proximity to be described as adjacent. Electrically conductive rail 60b in the form of a conductive metal strap is positioned over the top of terminal bars 14c and 26c on the adjacent modules 10e. Strap 60b has through holes positioned to mate with the through holes on terminal bars 26c and 14c of modules 10e and 10f respectively. Electrically conductive fasteners, in the FIG. 14A embodiment “carriage” type threaded bolts 46b, then secure the strap rail to both terminal bars and thereby a secure and robust electrical connection between terminal bars 26c and 14c is achieved. Simultaneously, the two modules 10e and 10f are affixed in adjacent positioning.

It is understood that the embodiments shown in FIGS. 13 and 14 and 14A may be further augmented with protective transparent sheets such as that indicated by numeral 50 of FIG. 10.

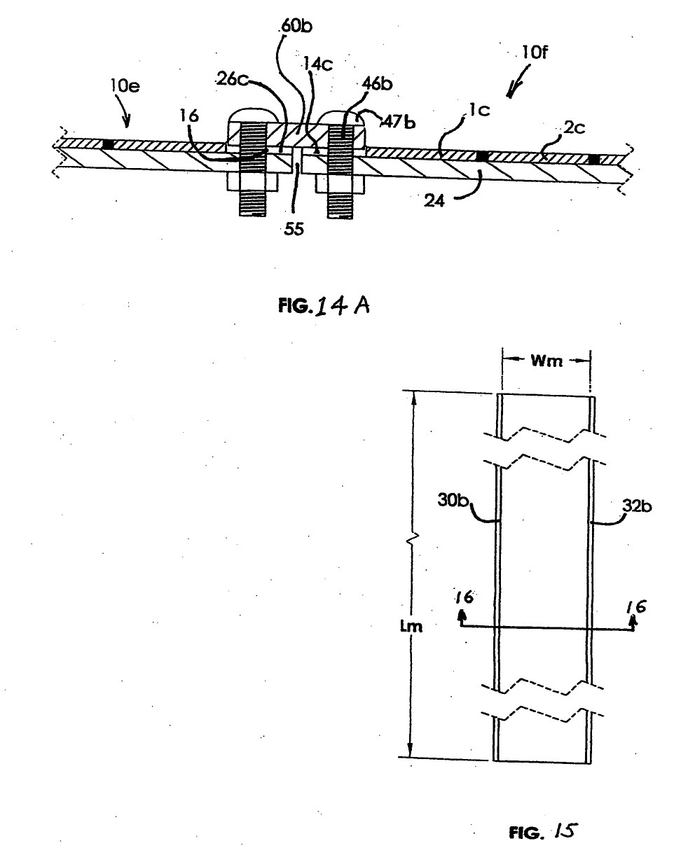

FIG. 15 is a top plan view of another structural embodiment of the inventive installations of the instant invention. FIG. 16 is a sectional view taken substantially from the perspective of lines 16-16 of FIG. 15. Reference to FIGS. 15 and 16 shows a structure comprising a pair of elongated rails 30b and 32b spanned by a rigid supporting sheet 68. Supporting sheet 68 may be chosen from any number of materials and forms, including honeycomb or expanded mesh forms. Sheet 68 may also be a composite structure of multiple materials and forms. The combination of rails 30b, 32b, and sheet 68 is seen to form an extended channel, which as will be seen has a width slightly larger than the width of the eventual applied module.

Continued reference to FIG. 15 suggests that the structure is receptive to a single module having a relatively long length (Lm). Indeed, such a structure is intended to receive and support a module of extended length. While prior art modules have restricted surface dimensions due to fabrication limitations and materials of manufacture, the referenced teachings of the Luch patents and disclosures introduce materials and forms capable of practical production of modules having extended dimensions, particularly in the length direction. Luch teaches technology to produce modules having a length limited only by the ability to properly accumulate them in a roll form. Modules having length in feet of two to three figures (i.e. 10 ft., 50 ft. 100 ft. 1000 ft.) are entirely reasonable using the Luch teachings. Modules having such extended length may be considered “continuous” and transported and installed in roll form. Thus, the dimension (Lm) in FIG. 15 may be considered to be of such extended dimension. Width “Wm” in FIG. 15 may correspond to a module width dimension which may be manageable from a handling and installation standpoint. By way of example, “Wm” may be less than 10 ft. (i.e. 4 ft., 8 ft.) but widths “Wm” greater than 10 ft. are certainly possible.

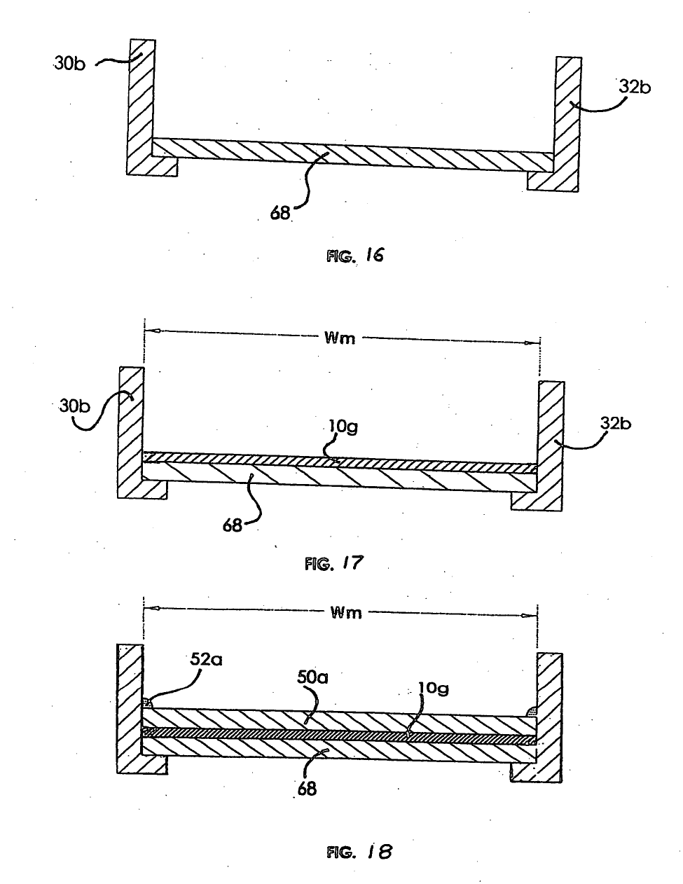

FIG. 17 is a sectional view similar to FIG. 16 following application of a extended length (continuous) form of photovoltaic module 10e. It is envisioned that such a module would be conveyed to the installation site and simply rolled out following the outline of the channel frame formed by rails 30b, 32b and support 68 which is clearly shown in FIG. 16. An appropriate structural adhesive (not shown in FIG. 17) may be used to fix the module 10g securely to sheet 68.

FIG. 18 is a view similar to FIG. 17 but after application of an optional transparent cover sheet 50a and sealing material 52a. As has previously been explained, sheet 50a and sealing material 52a may be useful in extending the life of certain environmentally sensitive photovoltaic materials.

In the supporting structure embodiments shown herein, some embodiments depict “rail” members in the form of material having angled cross sections. While one will realize that such a cross section is not necessary to accomplish the structural and connectivity aspects of the invention, such a geometry forms a convenient recessed pocket or frame to readily receive the sheetlike forms being combined with the structures. In addition, the vertical wall portion of the angled structure offers a containment or attachment structure for appropriate edge protecting sealing materials.

### CONCEPTUAL EXAMPLES

### Example 1

Modules of multiple interconnected cells comprising thin film CIGS supported by a metal foil are produced. Individual multi-cell modules are constructed according to the teachings of the Luch patent application Ser. No. 11/980,010. As noted, other methods of module construction may be chosen. Each individual cell has linear dimension of width 1.97 inches and length 48 inches (4 ft.). 48 of these cells are combined in series extending approximately 94.5 inches in the module length direction perpendicular to the 48 inch length of the cells. Such a modular assembly of cells is expected to produce electrical components of approximately 24 open circuit volts and 15 short circuit amperes. A terminal bar is included to contact the bottom electrode of the cell at one end of the 8 ft. module length. A second terminal bar is included to contact the top electrode of the cell at the opposite end of the 8 ft. length. The terminal bars are readily included according to the teachings of the referenced Luch patent application Ser. No. 11/980,010. The terminal bars need not be of extraordinary current carrying capacity because their function is only to convey current a relatively short distance and to serve as a convenient structure to interconnect to adjacent mating conductive structure. The individual modules may be adhered to an appropriate support structure as taught above.

In a separate operation, a terrestrial site is cleared and graded to form a landscape characterized by a combination of repetitive elongate hills adjoining elongate furrows. The linear direction of the elongate hills and furrows and the inclination angle from the base of a furrow to the peak of an adjoining hill is adjusted according to the latitude of the site, as those skillful in the art will appreciate. Mounting piers are situated to emanate from the ground at the top of the hills and base of the furrows. The mounting piers are positioned repetitively along the length of the hills and furrows. As an example, the piers may be positioned repetitively separated by about 4 to 8 feet, although this separation will be dictated somewhat by the strength of the eventual supporting structure spanning the distance between piers. Finally, a supporting structure, including the elongate rails such as the angled rails as described above, are attached to the piers extending along the length of the hills and furrows. The supporting structure need not be excessively robust, since the modules are relatively light. Should rail strength or current carrying capacity be of concern, other structural forms for the rails, such as box beam structures or increased cross sections, may be employed. Indeed, increased rail cross section may become appropriate as rail length increases.

Installation proceeds by repetitive placement and securing multiple module sheets along the length of the rails. The thin film modules are relatively light weight, even at expansive surface areas. For example, it is estimated that using construction as depicted in FIGS. 1 through 3, the 4 ft.×8 ft. module of this example 1 would weigh less than 100 pounds. Thus easy and rapid mounting may be achieved by a 2 man team.

Should the mounting of the modules be in a parallel arrangement such as depicted in FIGS. 4 through 10, the elongate rails are constructed of conductive material such as aluminum or copper. Expected current increases in increments with the placement of each individual module but the expected voltage stays substantially constant along the length of the rails. The expected voltage from the 4 ft. by 8 ft. conceptual module is a maximum of about 24 volts, not enough to pose an electrical shock hazard. In addition, the oppositely charged rails are separated by 8 ft. Thus the oppositely disposed rails need not be heavily insulated.

A typical length for the rails may be greater than 10 ft. (i.e. 50 ft., 100 ft., 200 ft., 300 ft.) As the expected current increases at greater length, the cross sectional area of the supporting rails may also be increased to accommodate the increasing current without undue resistive power losses. The rails thus serve as the conduit to convey photogenerated power from the multiple modules in parallel connection to a defined location for further treatment.

Should the modules be arranged in series, as depicted in the embodiments of FIGS. 11 through 14, voltage will increase along the length of the mounting structure but the current will remain substantially constant. In the case of the example modules (4 ft.×8 ft. with cell widths of 1.97 inches and length of 48 inches, the current will remain at about 15 amperes as the power is collected through the multiple modules mounted in series. However, open circuit voltage will increase by about 24 volts as the power traverses each 8 ft. length of module. For a 104 ft. accumulated length of modules, the open circuit voltage will have accumulated to about 312 volts. Thus, in this case precautions must be observed regarding electrical shock danger.

### Example 2

In this example, site preparation is generally similar to that of Example 1 and structures are constructed according to the embodiment of FIG. 16. Modules are manufactured and shipped to the installation site in the form of rolls of extended length. For example, a continuous roll of CIGS cells interconnected in series to form a single module is produced. Individual cells have a width dimension of 1.97 inches and length of 48 inches. The module is 100 ft. in length and has terminal bars at each end of the 100 ft. length. There are 608 series connected cells and the terminal bars are about 1 inch wide and extend across substantially the entire 48 inch width of the module. The modules are accumulated in rolls each of which comprises a 100 ft. module as described.

The rolls are shipped to the installation site. There, workers position one end at the start of an extended channel such as depicted in FIG. 16. Such a 100 ft. roll of thin film module on a 0.001 inch metal foil substrate is estimated to weigh less than 40 pounds so that the installation could proceed with as little as a two man crew. Electrical connections to a buss bar mounted on the channel's end may be made using the electrically conductive fasteners and techniques such as hereinbefore discussed in reference to FIGS. 7-10, and 13-14. The module is unrolled using the channel as a guide, optionally using a structural adhesive to fix the module to the substrate. Finally, electrical connections to a buss bar at the opposite end of the structure may be made using the electrical and structural fasteners as herein taught.

The extended length module has a total active surface area of 400 square feet. It would be expected to generate approximately 3600 peak watts. Output current would be only about 15 amperes so that conductors need not be overly robust. Closed circuit voltage would be about 310 volts so that safety precautions and security concerns would have to be addressed.

In a comparison of the conceptual examples, the parallel mounting arrangement presented in FIGS. 4 through 10 has the advantage of low shock hazard, easy installation and replacement. However, this arrangement requires attention to conductor cross sections to minimize resistive losses from high currents. The series arrangement presented in FIGS. 11 through 14 has the advantage of low currents and therefore low costs of conductors. This arrangement also is characterized by relatively facile installation and replacement. However, this arrangement is characterized by high voltage accumulation and resulting shock potential. Finally, the extended length module arrangement of FIGS. 15 through 18 is likely the simplest installation requiring a minimum of interconnections and facile module shipping and placement. This arrangement produces high voltage buildup and inability to easily replace defective cells or portions of modules.

Finally it should be clear that while the mounting structures illustrate in the embodiments accomplish supporting modules above a base surface such as the ground (earth), the installation principles taught herein are equally applicable should one use a roof or other surface to support the module.

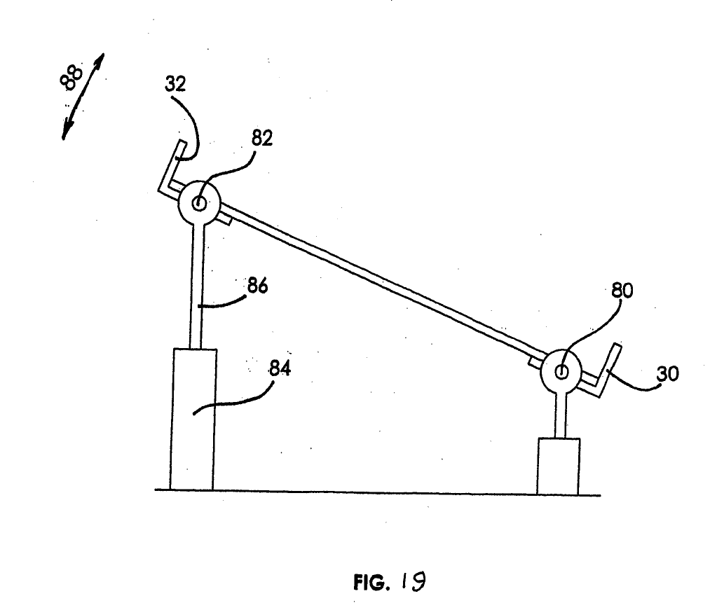

An additional embodiment of the instant invention is presented in FIG. 19. In the FIG. 19 arrangement one of the mounting rails 30 is mounted on a pivoting support 80. The opposite rail 32 is also mounted to a pivoting support 82. Pivoting support 82 is further mounted to a jacking device 84 as shown. The jacking device 84 may comprise any number of means, such as motorized jack screw or even a hydraulic cylinder. The jacking device 84 provides adjustable extension of arm 86 which accomplishes rotation of the mounted module along an arc generally indicated by double ended arrow 88. Thus, the multiple modules mounted on rails may be conveniently tilted appropriately according to positional latitude or season. Since the modules are relatively large yet lightweight this tilting mechanism may be accomplished with a minimum of complexity.

Although the present invention has been described in conjunction with preferred embodiments, it is to be understood that modifications, alternatives and equivalents may be included without departing from the spirit and scope of the inventions, as those skilled in the art will readily understand. Such modifications, alternatives and equivalents are considered to be within the purview and scope of the invention and appended claims.

What is claimed is:

1. A photovoltaic energy installation, said installation comprising a structure positioned and adapted to mate with a first photovoltaic module,
said photovoltaic module comprising multiple interconnected photovoltaic cells and further comprising terminal bars having opposite polarity,
said structure comprising one or more rails, a first of said rails comprising an elongate form of electrically conducting metal,
said installation characterized as having a first electrical connection between a first of said terminal bars and said first of said rails and,
said first connection being achieved absent the use of flexible metallic leads extending from a surface of said module.

2. The installation of claim 1 wherein said cells comprise thin film semiconductor material.

3. The installation of claim 1 wherein said cells comprise a metallic foil substrate.

4. The installation of claim 1 further comprising a second of said modules, said second module attached to said first rail in substantially the same way as said first module.

5. The installation of claim 1 wherein said module has a length dimension and a width dimension, and said cells have a dimension substantially equal to said module width dimension, and wherein said module terminal bars are positioned at opposite ends of the module length dimension.

6. The installation of claim 5 wherein said terminal bars extend substantially over the entirety of said module width dimension.

7. The installation according to claim 1 wherein said terminal bars provide upward facing conductive surfaces.

8. The installation of claim 1 wherein said terminal bars have attachment structure intended to mate with complimentary attachment structure present on said electrically conductive metal.

9. The installation of claim 8 wherein said terminal bar attachment structure comprises through holes.

10. The installation of claim 1 wherein a first of said terminal bars are characterized as having oppositely facing conductive surfaces, said conductive surfaces being in electrical communication.

11. The installation of claim 1 wherein said first electrical connection is achieved with an electrically conducting fastener.

12. The installation of claim 11 wherein said fastener is a mechanical fastener chosen from the group comprising a threaded bolt, an expansion bolt, a metal anchor a rivet or a U-bolt.

13. The installation of claim 1 wherein said first rail is part of a supporting structure for said module, said supporting structure serving to support said module above a base surface thereby leaving a space between said module and said base surface.

14. The installation of claim 13 wherein an electrically conducting fastener serves to both fasten the module to said supporting structure and also to convey current from said module to said first rail.

15. The installation of claim 1 wherein said first rail comprises material chosen from the group aluminum and copper.

16. The installation of claim 1 wherein said first module has a length and a width, said module comprising multiple cells connected in series, said cells having a dimension substantially equal to said module width, said cells arranged such that voltage increases progressively in the direction of said module length while being constant in the direction of said module width.

17. The installation of claim 1 wherein said first rail varies in cross section along its length in order to minimize resistive losses.

18. The installation of claim 1 wherein said first rail serves as a manifold for conveyance of said power produced by a multiple said modules.

19. The installation of claim 1 wherein said module is directly attached to a roof

20. The installation according to claim 13 wherein a portion of said supporting structure may be vertically adjusted in order to vary the tilt of the module relative to the horizontal.

21. A photovoltaic energy installation, said installation comprising a structure positioned and adapted to mate with two or more photovoltaic modules,
said photovoltaic modules comprising multiple interconnected photovoltaic cells and further comprising terminal bars having opposite polarity,
a first of said terminal bars associated with a first of said modules electrically connected to a second of said terminal bars associated with a second of said modules, said first and second terminal bars having opposite polarity,
said electrical connection being achieved through an electrical conductor extending from said first terminal bar to said second terminal bar,
said conductor affixed to said first terminal bar by a mechanical fastener.

22. The installation of claim 21 wherein said electrical conductor also secures said first and second modules in adjacent positioning.

23. The installation of claim 21 wherein said electrical conductor is secured to said first and second modules with mechanical fasteners.

24. The installation of claim 21 wherein said electrical conductor also serves as a fastener to attach said first of said modules to said structure.
